(19) United States
(12) Patent Application Publication
(10) Pub. No.: US 2012/0056645 A1
(43) Pub. Date: Mar. 8, 2012

(54) Analog to Digital Acquisition Eliminating Uncertainty of Level Test in High Noise Environments

(75) Inventor: Denny D. Beasley, La Grange Park, IL (US)

(73) Assignee: ROBERTSON TRANSFORMER CO., Blue Island, IL (US)

(21) Appl. No.: 13/255,385

(22) PCT Filed: Mar. 10, 2010
(86) PCT No.: PCT/US10/26797

§ 371 Date: Nov. 16, 2011

Related U.S. Application Data
(60) Provisional application No. 61/158,819, filed on Mar. 10, 2009.

(51) Int. Cl. H03K 5/153; G01R 19/00

(52) U.S. Cl. 327/90; 324/76.11

(57) ABSTRACT

A method of determining the quality of a sensed signal has capturing, comparing, categorizing, and a decision-making steps. The capturing step is used to capture a plurality of signals. A magnitude of each of the plurality of signals is compared to a predetermined value to determine a relationship between each of the plurality of signals to the predetermined value. A result of each comparison is categorized according to one of a plurality of predetermined criteria. The categorizing step is repeated at least until a predetermined number of results has been reached in at least one of the plurality of predetermined criteria. A decision is made based on which of the plurality of predetermined criteria reaches the predetermined number.

### CROSS-REFERENCE TO RELATED APPLICATIONS

The present invention claims the benefit of U.S. Provisional Patent Application No. 61/158,819 filed Mar. 10, 2009, the contents of which are incorporated herein by reference.

### FEDERALLY SPONSORED RESEARCH OR DEVELOPMENT

N/A.

### TECHNICAL FIELD

The invention relates to transformation of analog data to digital using a probability function to eliminate uncertainty in high noise environments.

### BACKGROUND OF THE INVENTION

FIG. 1 shows several of the typical methods available to control band-pass and improve the signal to noise ratio of the signal in question. As shown in FIG. 2, an input signal (1) is input to a control amplifier where the feedback element Z (27) provides feedback to produce a processed signal (4) for use in a digital capture. FIG. 2 shows three typical scenarios: high pass (5), where only frequencies at and above F4 (9) and rejected from F0 (10) to F4 (9) are passed; low pass (6), where signals below F3 (11) to F0 (10) are passed; and narrow band (7) of frequencies, where only a range of frequencies such as between F1 (13) and F2 (12) are passed. However, it should be noted that a single amplifier is shown for ease of explanation, many of these circuits are multi-stage arrangements that can have very complex band pass, gain and noise requirements. The effort is to eliminate signals that are not pertinent to the target signal. A signal not well related to the sensed phenomenon, once captured, will reduce the effectiveness of the signal to elicit the correct control action.

The use of low cost microprocessors has become widespread; however, the interface of the digital to the analog domain is still an area that is encumbered with analog circuitry. Typically, an analog signal is processed to eliminate unwanted signals. This step helps in controlling the band pass of a signal to be sensed.

### SUMMARY OF THE INVENTION

One aspect of the present invention is directed to a method of determining the quality of a sensed signal. The method comprises the steps of: capturing a plurality of signals; comparing a magnitude of each of the plurality of signals to a predetermined value to determined a relationship between each of the plurality of signals to the predetermined value; categorizing the relationship resulting from each comparison according to one of a plurality of predetermined criteria wherein the categorizing step is repeated at least until a predetermined number of results has been reached in at least one of the plurality of predetermined criteria; and making a decision based on which of the plurality of predetermined criteria reaches the predetermined number.

The first aspect of the invention may include one or more of the following features, alone or in any reasonable combination. The method may further comprise the step of: determining an elapsed time for reaching the predetermined number of results in the at least one of plurality of predetermined criteria. The decision-making step may be further based on a duration of time from the determining an elapsed time step. The method may further comprise the step of: generating a signal based at least in part based on which of the plurality of predetermined criteria reaches the predetermined number. Each result may be recorded in one of a plurality of registers corresponding to the plurality of predetermined criteria. The method may further comprise the steps of: comparing the magnitude of each of the plurality of signals to a second predetermined value to determined a relationship between each of the plurality of signals to the second predetermined value; and categorizing the relationship resulting from each comparison to the second predetermined value according to one of a second set of predetermined criteria wherein the categorizing step is repeated at least until a second predetermined number of results has been reached in at least one of the second set of predetermined criteria. The plurality of predetermined criteria may comprise a greater than condition, a less than condition and an equal to the predetermined value condition. The method may further comprise the steps of: determining a less than condition in the comparing and categorizing steps; performing a second comparison of the magnitude of a responsible captured signal of the plurality of captured signals to a second predetermined value wherein the responsible captured signal triggered the less than condition when compared to the predetermined value; and performing a second categorizing step wherein a second relationship resulting from the second comparison is categorized according to one of a second set of a plurality of predetermined criteria.

Aspect of the invention is directed to a method of filtering an analog signal. The method comprises the steps of: establishing a signal target value; establishing a predetermined test condition; capturing a plurality of data points of an incoming analog signal; comparing each of the plurality of data points against the target value; categorizing each result of the comparing step according to a plurality of predetermined metrics; and selecting one of the plurality of predetermined metrics upon meeting the predetermined test condition.

The second aspect of the invention may include one or more of the following features, alone or in any reasonable combination. The method may further comprise the step of: measuring an elapsed time for the predetermined condition to be met. The method may further comprise the step of: generating a signal based at least in part on the selected predetermined metric and the elapsed time for the predetermined condition to be met. The predetermined test condition comprises a desired number of information bits. The plurality of predetermined metrics may comprise at least three eight bit registers. The method may further comprise the step of: generating a signal in response to which of the plurality of predetermined metrics is selected.

A third aspect of the invention is directed to a method to capture analog information comprising the steps of: using simple methods known in the art and simple native machine behavior to stabilize said information by inherently while simultaneously make mutually exclusive non ambiguous decisions. An indication of data capture quality may be provided by the time it takes to acquire data to the decision stage.

Other features and advantages of the invention will be apparent from the following specification taken in conjunction with the following drawings.

### BRIEF DESCRIPTION OF THE DRAWINGS

To understand the present invention, it will now be described by way of example, with reference to the accompanying drawings in which:

FIG. 1 is a typical analog processing circuit and graphs showing typical high pass, low pass and narrow band analog signal processing;

FIG. 2 is a basic flow diagram of analog data reduced to digital;

FIG. 3A is a typical Gaussian distribution of captured data spread;

FIG. 3B is a typical Gaussian distribution of captured data spread;

FIG. 4 is a flowchart showing use of digital capture without pre-processing;

FIG. 5 is a flowchart of the present invention;

FIG. 6A is a flowchart of a decision step of the present invention;

FIG. 6B is a graph of bin data; and

FIG. 7 is a flowchart the time-to-decision as a parameter of control.

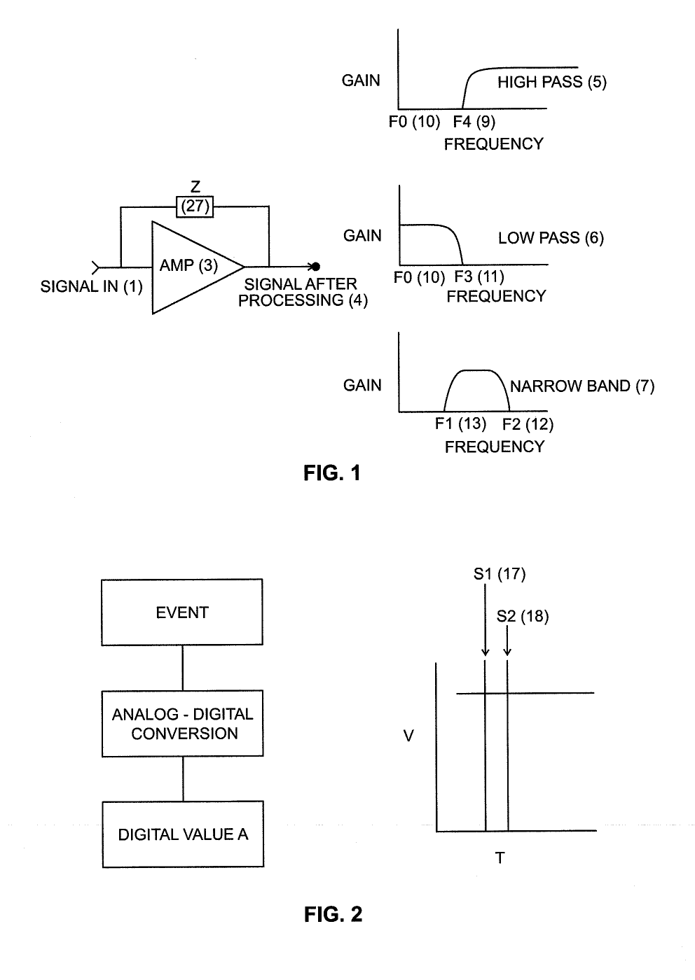

### DETAILED DESCRIPTION

While this invention is susceptible to embodiments in many different forms, there is shown in the drawings and will herein be described in detail preferred embodiments of the invention with the understanding that the present disclosure is to be considered as an exemplification of the principles of the invention and is not intended to limit the broad aspect of the invention to the embodiments illustrated.

One aspect of the present invention is to eliminate the complexity of prior art methods to control band-pass and improve the signal to noise ratio of the signal by using a simplest raw data capture, samples S1 (17) and S2 (18), as exemplified in FIG. 2. In many low cost products, the signal processing makes the expense of using low cost microcontrollers cost prohibitive. Use of this invention will permit larger scale use of intelligent devices to optimize the efficiency of any powered device by accurately sorting the signal and unwanted noise. The method makes decisions based on probability of a value and not a fixed level capture. However, the number of processor steps to perform this action is very low, and the method requires no high level numeric processing such as the probability density function (100):

$$f ( x ) = \frac{e - \frac{{x}^{2}}{2}}{\sqrt{2 π}} \qquad ( 100 )$$

where x is the probability of an event.

Evaluating this algorithm is well beyond the numeric processing capability of low cost digital controllers, or the large processing burden destroys the effectiveness of these devices to accomplish the needed tasks by making their response time quite slow.

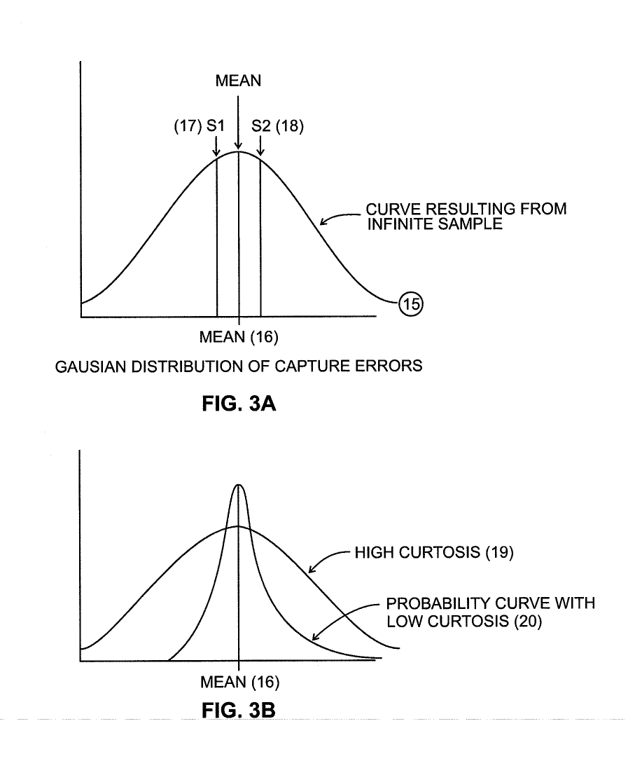

A typical distribution curve (15) is shown in FIG. 3A. The distribution is centered around a mean value (16) of a sampled signal, S1 (17) and S2 (18). The sampled signal is sampled over a very short interval and can have a high probability of being in error in high noise environments. If this occurs, fewer captures will be nearer to the correct value. This leads to a distortion of the probability curve. This distortion is referred to as the kurtosis of the probability curve, or the spread of values around the mean. FIG. 3B shows this effect. The high kurtosis curve (19) shows values frequently ranged far from the mean value (16). The low kurtosis curve (20) shows that the captured values grouped closely to the mean value. From this, we can conclude that although the scatter is large in the high kurtosis curve, it does not destroy the mean value. It simply requires a larger number samples to find it. For a digital system, more samples multiplied by the number of design samples per second would lead to the conclusion that in a noisy environment, it would take more time to come to a conclusion on the sampled data.

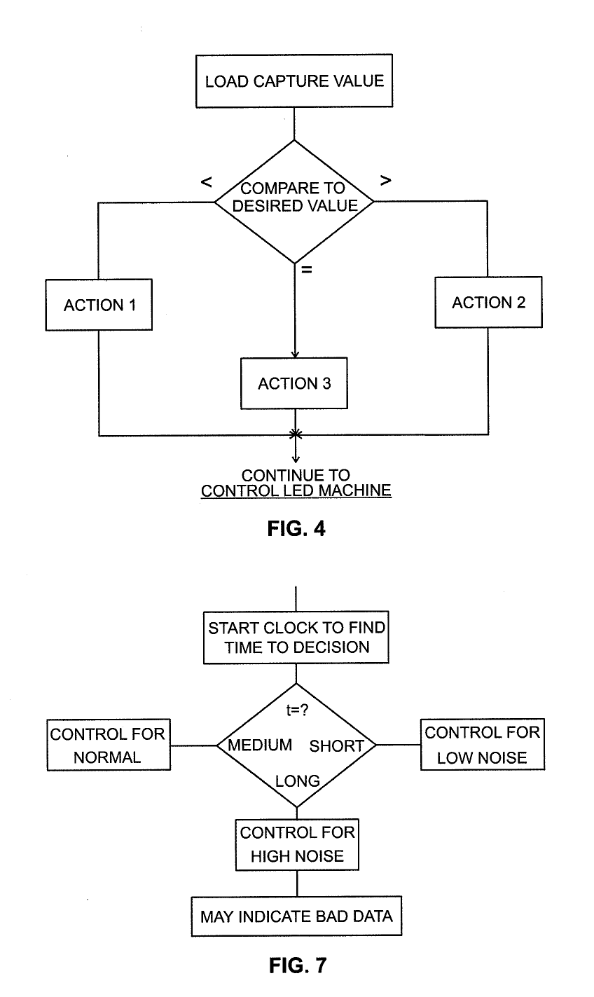

The above discussion demonstrates the folly of using a direct capture of the sensed signal to direct a controller to act on a controlled system as shown in FIG. 4. FIG. 4 typifies actions taken on the basis of a single capture and compare, or even averaged signals. A value is captured in the “load capture value” step and then is compared to a reference digital value in the “compare to desired value” step thus providing three possible outcomes, greater than “>”, equal to “=”, or less than “<.” This simple scenario can lead to unstable operation and unwanted, potentially harmful events, if in a high noise environment. This is so because each sample is a very narrow time slice of the actual event. Thus, if a sample of the analog to digital converter occurred during or near a transient event, it may be related to the process being monitored, although bearing no information to the parameter desired. The information will be masked or tainted by the event in that time slice and thus be effectively useless. If an action is taken based on this tainted data, the outcome can be disastrous. In other words, the mean value (16) of FIG. 2 is the maintained value, and the control action, i.e. correctness, is only as accurate as the probability of the sample capture correctness.

The criteria for the acquisition of the desired value is to first sample and compare that sample to some value or sets of values to position it to the target value. In the following description, an 8 bit controller is used for simplicity; however, the controller can be of any internal bus size (16, 32, 63, 128, etc.) without departing from the spirit of the invention.

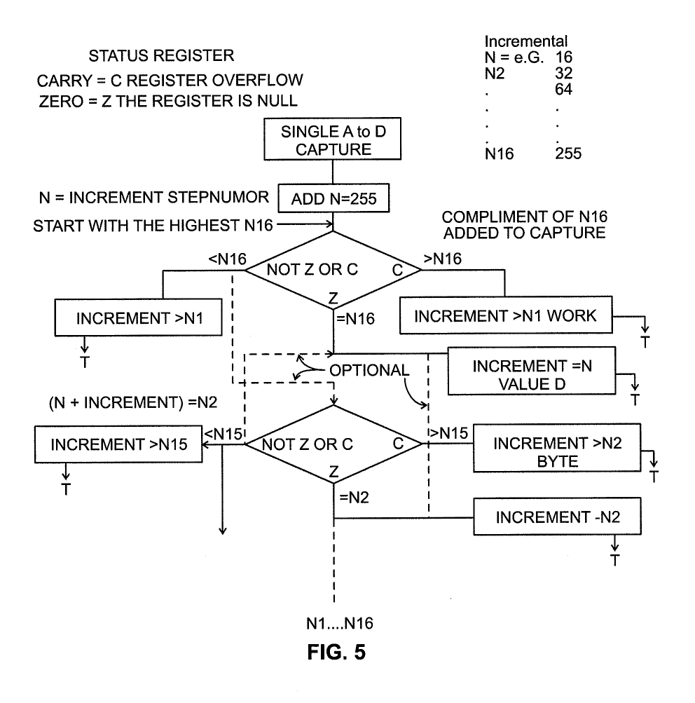

When register operations are performed, the status-byte records several possible outcomes, null or zero, an overflow or carry, and no change of state, thus providing three possible conditions. In FIG. 5, if the outcome register has had an overflow, the digital register residual of this event is recorded in specific bits of an 8 bit word called the “status” as described above. The bit that flags the overflow is the carry bit, and if the register has a null or zero value, then the Z bit is set. Typically, there is even more information stored in the status byte, but this is all that is needed to make very complex decisions on captured signals, which is an object of this invention.

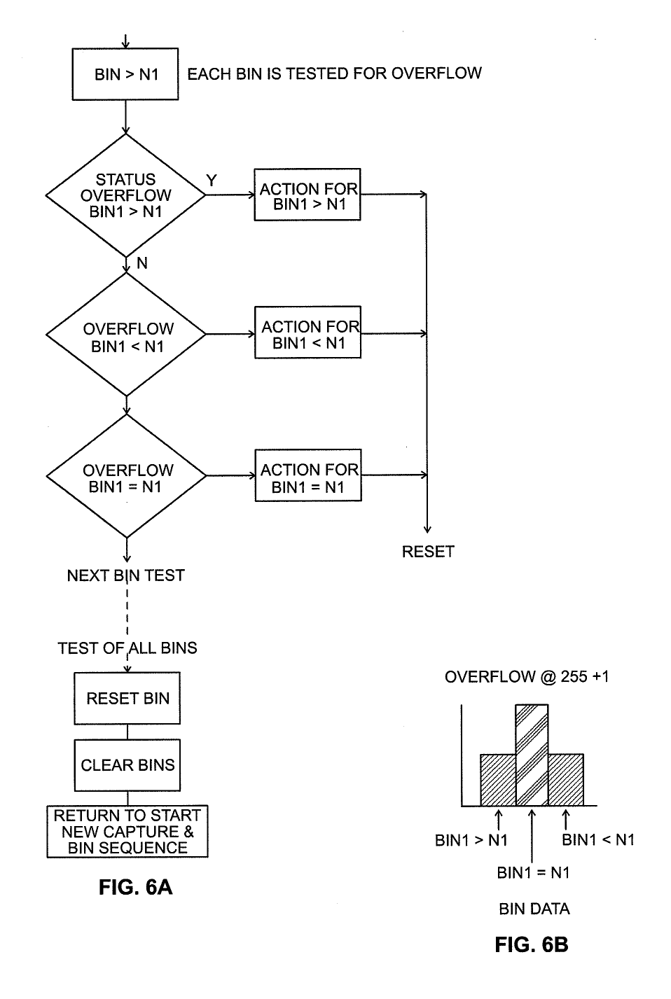

This is accomplished in the decision step illustrated in FIG. 6A. Using the simplest example of a set point control, N16 is the target value. Thus, in one test, it can be determined if the value is larger >N16, smaller <N16, or the same. This is accomplished by adding the complimentary value of the set point to the actual captured value. The result is then determined to be larger, smaller, or the same by the flags set in the status byte. If a zero flag is set, the captured value is equal to N16. If the overflow is set, then it is larger than N16. As the program runs each time, a capture is made. The occurrence of the status flag event increments the corresponding bin or the binary-word receives an increment. Eventually, one of the bins will be at 255, and on the next increment, it will have its rollover to zero and have both the Z (zero status byte set) and C (carry bit set). This distinction is important. Before the first sample is taken, all of the bins will be at zero and will test with the Z bit set. Only after a bin has progressed from zero to its maximum value plus one, will the two bit set.

Once one of the bins Z and C flags are set, it stops further captures and acts on the directives needed for that condition. For example, if the bin “=N16” is tested true, we are at the desired condition, and, therefore, no action is taken. Before the next capture, all the bins are emptied and the procedure begins again.

The probability of an exact hit for the “=N16” bin is small as it represents a low probability in a high noise to signal environment. This would be the condition of a large kurtosis on the distribution curve. This would be corrected by having two points distributed around the set point, or N15 as shown in FIG. 5. In a multipoint test scenario, the test would be started at the maximum and work its way to the minimum. N16 would be tested if it were less than capture. The next test would be N15. If N15 is less than captured, the value lies between N16 and N15.

The process can be as resolute as needed to make higher levels. In the limit, the number of bins could equal the number of bits of a word. Each value or 255 of an 8 bit word could be a bin. If in a low noise environment, and if the capture were exact every time, it would take only 255 captures to make a determination. If in an extremely noisy environment, it could take (255−7)*(255) or 63240 samples.

The time taken to have a bin fill to overflow becomes a metric of the quality of the sensed signal. For example, a long capture, indicating high noise, could indicate that the controlled system has a problem and is not operating optimally. This can be seen in FIG. 7. The capture length adds secondarily to the captured data by providing a measure of probability density curve kurtosis—amount of scatter from the median value. This is information about the local electrical environment from which the data capture is derived. A high kurtosis would mean that conditions of higher uncertainty exists and direct the logic to take a more cautious action on the data.

Another feature of the present invention is that the method will always make a decision. There is no confusion in the decision making as only one bin can be incremented at a time so only one will win the probability race. However, if all there is noise, then the decision will take on a random order. This is where the quality factor can be used to flag data as useless if the decision process time is excessive.

The term “plurality” as used herein is intended to indicate any number greater than one, either disjunctively or conjunctively as necessary, up to an infinite number.

While the specific embodiments have been illustrated and described, numerous modifications come to mind without significantly departing from the spirit of the invention and the scope of protection is only limited by the scope of the accompanying Claims.

What is claimed is:

1. A method of determining the quality of a sensed signal comprising the steps of:
capturing a plurality of signals;
comparing a magnitude of each of the plurality of signals to a predetermined value to determined a relationship between each of the plurality of signals to the predetermined value;
categorizing the relationship resulting from each comparison according to one of a plurality of predetermined criteria wherein the categorizing step is repeated at least until a predetermined number of results has been reached in at least one of the plurality of predetermined criteria; and
making a decision based on which of the plurality of predetermined criteria reaches the predetermined number.

2. The method according to claim 1 further comprising the step of:
determining an elapsed time for reaching the predetermined number of results in the at least one of plurality of predetermined criteria.

3. The method of claim 2 wherein the making the decision step is further based on a duration of time from the determining an elapsed time step.

4. The method of any of the preceding claims further comprising the step of:
generating a signal based at least in part based on which of the plurality of predetermined criteria reaches the predetermined number.

5. The method of any preceding claim wherein each result is recorded in one of a plurality of registers corresponding to the plurality of predetermined criteria.

6. The method of any preceding claim further comprising the step of:
comparing the magnitude of each of the plurality of signals to a second predetermined value to determined a relationship between each of the plurality of signals to the second predetermined value; and
categorizing the relationship resulting from each comparison to the second predetermined value according to one of a second set of predetermined criteria wherein the categorizing step is repeated at least until a second predetermined number of results has been reached in at least one of the second set of predetermined criteria.

7. The method of claim 1 wherein the plurality of predetermined criteria comprises a greater than the predetermined value condition, a less than the predetermined value condition and an equal to the predetermined value condition.

8. The method of claim 7 further comprising the steps of:
determining a less than the predetermined value condition in the comparing and categorizing steps;
performing a second comparison of the magnitude of a responsible captured signal of the plurality of captured signals to a second predetermined value wherein the responsible captured signal triggered the less than the predetermined value condition when compared to the predetermined value; and
performing a second categorizing step wherein a second relationship resulting from the second comparison is categorized according to one of a second set of a plurality of predetermined criteria.

9. A method of filtering an analog signal comprising the steps of:
establishing a signal target value;
establishing a predetermined test condition;
capturing a plurality of data points of an incoming analog signal;
comparing each of the plurality of data points against the target value;
categorizing each result of the comparing step according to a plurality of predetermined metrics; and
selecting one of the plurality of predetermined metrics upon meeting the predetermined test condition.

10. The method of claim 9 further comprising the step of:
measuring an elapsed time for the predetermined condition to be met.

11. The method of claim 11 further comprising the step of:
generating a signal based at least in part on the selected predetermined metric and the elapsed time for the predetermined condition to be met.

12. The method according to any of claims 9 through 11 wherein the predetermined test condition comprises a desired number of information bits.

13. The method according to any preceding of claims 9 through 12 wherein the plurality of predetermined metrics comprises at least three eight bit registers.

14. The method of claim 13 further comprising the step of:
generating a signal in response to which of the plurality of predetermined metrics is selected.

15. The method of claim 9 further comprising the step of:
generating a signal in response to which of the plurality of predetermined metrics is selected.

16. A method to capture analog information comprising the steps of:
using simple methods known in the art and simple native machine behavior to stabilize said information by inherently while simultaneously make mutually exclusive non ambiguous decisions.

17. The method of claim 1 wherein an indication of data capture quality is provided by the time it takes to acquire data to the decision stage.
